(19) United States
(12) Patent Application Publication
(10) Pub. No.: US 2022/0244641 A1
(43) Pub. Date: Aug. 4, 2022

(54) POLYIMIDE RESIN AND POSITIVE-TYPE PHOTOSENSITIVE RESIN COMPRISING THE SAME

(71) Applicant: LG Chem, Ltd., Seoul (KR)

(72) Inventors: Jiyeon SUNG, Daejeon (KR); Minyoung Lim, Daejeon (KR)

(73) Assignee: LG Chem, Ltd., Seoul (KR)

(21) Appl. No.: 17/587,574

(22) Filed: Jan. 28, 2022

(30) Foreign Application Priority Data
Feb. 4, 2021 (KR) 10-2021-0015810

(51) Int. Cl. G03F 7/039; C08G 73/10

(52) U.S. Cl. CPC G03F 7/039; C08G 73/1007; C08G 73/1085

(57) ABSTRACT

An exemplary embodiment of the present application provides a polyimide resin in which the functional group represented by Chemical Formula 1 or 2 is bonded to at least one end of the polyimide resin.

### TECHNICAL FIELD

This application claims priority to and the benefit of Korean Patent Application No. 10-2021-0015810 filed in the Korean Intellectual Property Office on Feb. 4, 2021, the entire contents of which are incorporated herein by reference.

The present application relates to a polyimide resin and a positive-type photosensitive resin composition comprising the same.

### BACKGROUND ART

Currently, as a technique of forming a metal circuit pattern on a polymer film material used as a flexible printed circuit board and a packaging dielectric material, a method of preparing a metal circuit pattern by forming a circuit pattern having a predetermined shape on the surface of a polymer on which a thin copper foil is stacked or deposited using a photoresist process, and etching copper has been generally and widely used.

As a method of forming a metal layer on a polymer material, a laminate method and a casting method, in which a polymer material is surface-modified by plasma ions, and then a conductive metal junction layer is formed on the surface of the polymer using a dry surface treatment technique such as sputtering or metal deposition, and then a metal film layer is formed on the surface of the conductive metal junction layer using an electroplating technique or a copper foil is directly bonded to the surface of the polymer material depending on the product conditions, have been used.

Recently, a process of metalizing a polymer film material using a wet surface treatment has been developed, but in this process, a metal circuit is also formed by forming a metal layer on a polymer material and then etching copper using a photoresist process. These methods have a problem in that it is not easy to form a relatively uniform metal layer and high production costs are required.

Meanwhile, electroless plating is a method of precipitating a metal film by reducing metal ions by electrons released by an oxidation reaction of a reducing agent comprised in a solution without using a DC power source, unlike electroplating, and not only the selection of the composition and treatment conditions of a plating solution, but also pretreatment are very important. In the multi-step electroless plating process, a catalyzation step which enables a metal to be precipitated on the surface of a polymer substrate by activating the surface of a polymer that is a non-conductor can be said to be the most important process that influences the physical properties and adhesive strength between the polymer and the metal.

However, in the case of the polymer material, low wetting properties and additive contamination generated during processing cause physical and chemical interference in the catalytic treatment and plating processes, and as a result, the adhesion between the polymer and the metal becomes extremely low.

To solve this problem, many surface treatment techniques are performed, and typically, methods of inducing chemical bonds of functional groups on the surface of the polymer using a solution of potassium hydroxide, and the like, and increasing a surface area due to surface irregularities have been used.

However, the above-described surface treatment technique has complicated process conditions, and has a limitation in enhancing the adhesion between a polymer and a metal only by the surface treatment technique. Therefore, there is a need for research on a method capable of improving the adhesion between a polymer and a metal in the art.

### DISCLOSURE

### Technical Problem

The present application has been made in an effort to provide a polyimide resin and a positive-type photosensitive resin composition comprising the same.

### Technical Solution

An exemplary embodiment of the present application provides
a polyimide resin in which a functional group represented by the following Chemical Formula 1 or 2 is bonded to at least one end of the polyimide resin.

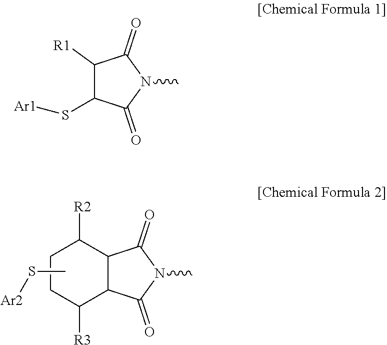

In Chemical Formulae 1 and 2,
[symbol] denotes a position to be bonded to the polyimide resin, respectively,

R1 to R3 are each independently hydrogen, a substituted or unsubstituted alkyl group, a substituted or unsubstituted aryl group, or a substituted or unsubstituted heteroaryl group, and R2 and R3 may be linked to each other to form a ring, and

Ar1 and Ar2 are each independently a substituted or unsubstituted heteroaryl group.

Further, another exemplary embodiment of the present application provides a method for preparing a polyimide resin, the method comprising:
preparing a polyimide resin in which a functional group represented by the following Chemical Formula 10 or 11 is bonded to at least one end of the polyimide resin; and
reacting the polyimide resin to which the functional group represented by Chemical Formula 10 or 11 is bonded with a heterocyclic compound comprising a thiol group (—SH).

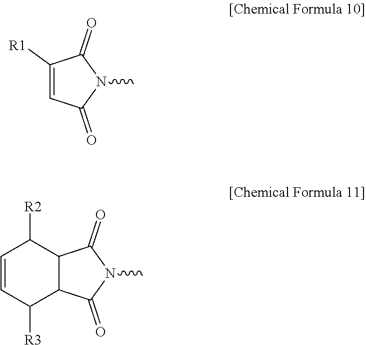

In Chemical Formulae 10 and 11,
[symbol] denotes a position to be bonded to the polyimide resin, respectively, and

R1 to R3 are each independently hydrogen, a substituted or unsubstituted alkyl group, a substituted or unsubstituted aryl group, or a substituted or unsubstituted heteroaryl group, and R2 and R3 may be linked to each other to form a ring.

In addition, still another exemplary embodiment of the present application provides a positive-type photosensitive resin composition comprising: a binder resin comprising the polyimide resin; a photo active compound; a cross-linking agent; a surfactant; and a solvent.

### Advantageous Effects

The polyimide resin according to an exemplary embodiment of the present application is characterized in that the adhesion strength to a metal can be improved by directly comprising a functional group having excellent adhesion to the metal in the polyimide resin.

Therefore, a photosensitive resin composition comprising the polyimide resin according to an exemplary embodiment of the present application can improve the adhesion strength to a metal even when the photosensitive resin composition does not comprise a separate adhesion promoter.

### BEST MODE

Hereinafter, the present application will be described in more detail.

When one member is disposed “on” another member in the present application, this comprises not only a case where the one member is brought into contact with another member, but also a case where still another member is present between the two members.

When one part “comprises” one constituent element in the present application, unless otherwise specifically described, this does not mean that another constituent element is excluded, but means that another constituent element may be further comprised.

In the present specification, the “polymer” means a compound composed of the repetition of repeating units (basic units). The polymer may be represented by a macromolecule or a compound composed of macromolecules.

The polyimide resin according to an exemplary embodiment of the present application is characterized in that a functional group represented by the following Chemical 1 or 2 is bonded to at least one end of the polyimide resin.

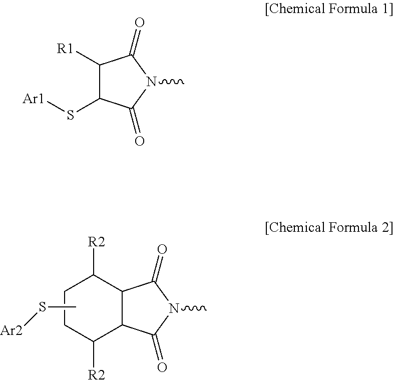

In Chemical Formulae 1 and 2,
[symbol] denotes a position to be bonded to the polyimide resin, respectively,

R1 to R3 are each independently hydrogen, a substituted or unsubstituted alkyl group, a substituted or unsubstituted aryl group, or a substituted or unsubstituted heteroaryl group, and R2 and R3 may be linked to each other to form a ring, and

Ar1 and Ar2 are each independently a substituted or unsubstituted heteroaryl group.

In an exemplary embodiment of the present application, Chemical Formula 1 may be represented by the following Chemical Formula 3 or 4.

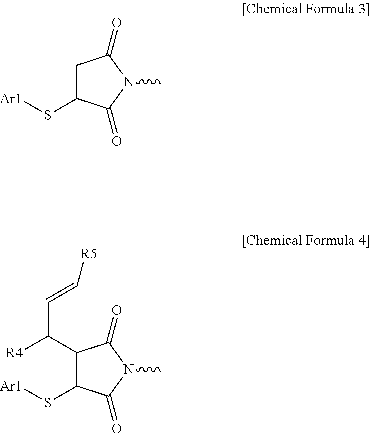

In Chemical Formulae 3 and 4,
[symbol] denotes a position to be bonded to the polyimide resin, respectively,

R4 and R5 are each independently hydrogen, or a substituted or unsubstituted alkyl group, and

Ar1 is a substituted or unsubstituted heteroaryl group.

In an exemplary embodiment of the present application, Chemical Formula 2 may be represented by any one of the following Chemical Formulae 5 to 9.

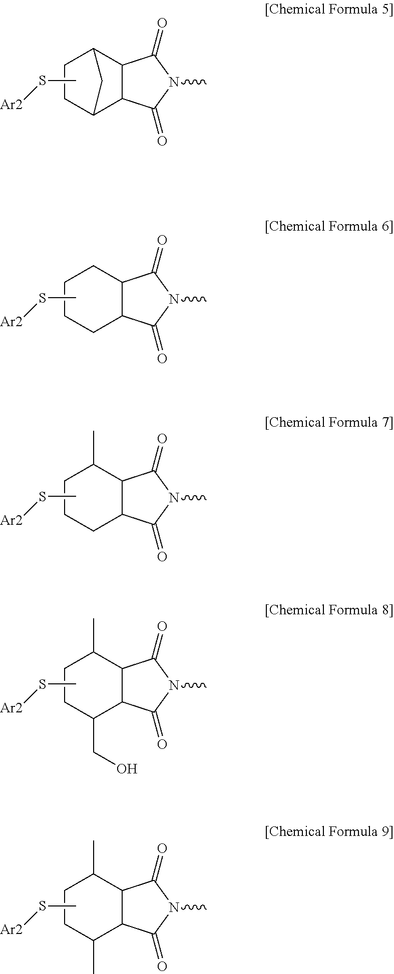

In Chemical Formulae 5 to 9,
[symbol] denotes a position to be bonded to the polyimide resin, respectively, and

Ar2 is a substituted or unsubstituted heteroaryl group.

In the present application, examples of substituents will be described below, but are not limited thereto.

In the present application, the term “substituted or unsubstituted” means being substituted with one or more substituents selected from the group consisting of deuterium; a halogen group; a nitrile group; a nitro group; a hydroxyl group; —COOH; an alkoxy group; an alkyl group; a cycloalkyl group; an alkenyl group; a cycloalkenyl group; an aryl group; a heteroaryl group; and a heterocyclic group comprising one or more of N, O, S or P atom or having no substituent.

In the present application, examples of a halogen group comprise fluorine, chlorine, bromine or iodine.

In the present application, the alkoxy group may be straight-chained or branched, and the number of carbon atoms is not particularly limited, but may be 1 to 30, specifically 1 to 20, and more specifically 1 to 10.

In the present application, the alkyl group may be straight-chained or branched, and the number of carbon atoms thereof is not particularly limited, but is preferably 1 to 60. According to an exemplary embodiment, the number of carbon atoms of the alkyl group is 1 to 30. According to another exemplary embodiment, the number of carbon atoms of the alkyl group is 1 to 20. According to still another exemplary embodiment, the number of carbon atoms of the alkyl group is 1 to 10. Specific examples of the alkyl group comprise a methyl group, an ethyl group, an n-propyl group, an isopropyl group, an n-butyl group, an isobutyl group, a tert-butyl group, an n-pentyl group, an n-hexyl group, an n-heptyl group, an n-octyl group, and the like, but are not limited thereto.

In the present application, a cycloalkyl group is not particularly limited, but has preferably 3 to 60 carbon atoms, and according to an exemplary embodiment, the number of carbon atoms of the cycloalkyl group is 3 to 30. According to yet another exemplary embodiment, the number of carbon atoms of the cycloalkyl group is 3 to 20. According to yet another exemplary embodiment, the number of carbon atoms of the cycloalkyl group is 3 to 6. Specific examples thereof comprise a cyclopropyl group, a cyclobutyl group, a cyclopentyl group, a cyclohexyl group, a cycloheptyl group, a cyclooctyl group, and the like, but are not limited thereto.

In the present application, the alkenyl group may be straight-chained or branched, and the number of carbon atoms thereof is not particularly limited, but is preferably 2 to 60. According to an exemplary embodiment, the number of carbon atoms of the alkyl group is 2 to 30. According to another exemplary embodiment, the number of carbon atoms of the alkyl group is 2 to 20. According to still another exemplary embodiment, the number of carbon atoms of the alkyl group is 2 to 10. Specific examples of the alkenyl group are preferably an alkenyl group in which an aryl group, such as a stylbenyl group and a styrenyl group, is substituted, but are not limited thereto.

In the present application, a cycloalkenyl group is not particularly limited, but has preferably 3 to 60 carbon atoms, and according to an exemplary embodiment, the number of carbon atoms of the cycloalkyl group is 3 to 30. According to yet another exemplary embodiment, the number of carbon atoms of the cycloalkyl group is 3 to 20. According to yet another exemplary embodiment, the number of carbon atoms of the cycloalkyl group is 3 to 6. Examples of the cycloalkenyl group are preferably a cyclopentenyl group and a cyclohexenyl group, but are not limited thereto.

In the present application, an aryl group is not particularly limited, but has preferably 6 to 60 carbon atoms, and may be a monocyclic aryl group or a polycyclic aryl group. According to an exemplary embodiment, the number of carbon atoms of the aryl group is 6 to 30. According to an exemplary embodiment, the number of carbon atoms of the aryl group is 6 to 20. Examples of a monocyclic aryl group as the aryl group comprise a phenyl group, a biphenyl group, a terphenyl group, and the like, but are not limited thereto. Examples of the polycyclic aryl group comprise a naphthyl group, an anthracenyl group, an indenyl group, a phenanthrenyl group, a pyrenyl group, a perylenyl group, a triphenyl group, a chrysenyl group, a fluorenyl group, and the like, but are not limited thereto.

In the present application, the heterocyclic group is a heterocyclic group comprising O, N or S as a heteroatom, and the number of carbon atoms thereof is not particularly limited, but is 2 to 30, specifically 2 to 20. Examples of the heterocyclic group comprise a thiophene group, a furan group, a pyrrole group, an imidazole group, a thiazole group, an oxazole group, an oxadiazole group, a triazole group, a pyridyl group, a bipyridyl group, a triazine group, an acridyl group, a pyridazine group, a qinolinyl group, an isoquinoline group, an indole group, a carbazole group, a benzoxazole group, a benzoimidazole group, a benzothiazole group, a benzocarbazole group, a benzothiophene group, a dibenzothiophene group, a benzofuranyl group, a dibenzofuran group, a tetrahydropyran group, and the like, but are not limited thereto.

In the present application, the above-described description on the heterocyclic group may be applied to a heteroaryl group except for an aromatic heteroaryl group.

In an exemplary embodiment of the present application, Ar1 and Ar2 of Chemical Formulae 1 and 2 may be each independently represented by any one of the following structural formulae.

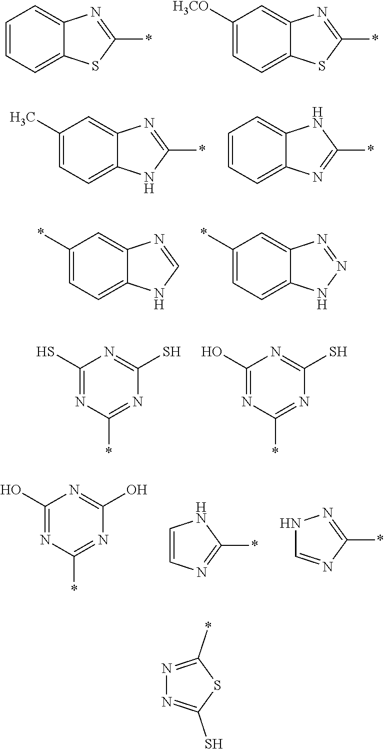

In the structural formulae, * denotes a position to be bonded to Chemical Formula 1 or 2.

In an exemplary embodiment of the present application, the polyimide resin may comprise a polymer product of an amine-based monomer and an anhydride-based monomer. As a polymerization process of the amine-based monomer and the anhydride-based monomer, a method known in the art may be used, except that the amine-based monomer and the anhydride-based monomer to be described below are used.

The amine-based monomer may be selected from the following structural formulae, but is not limited thereto.

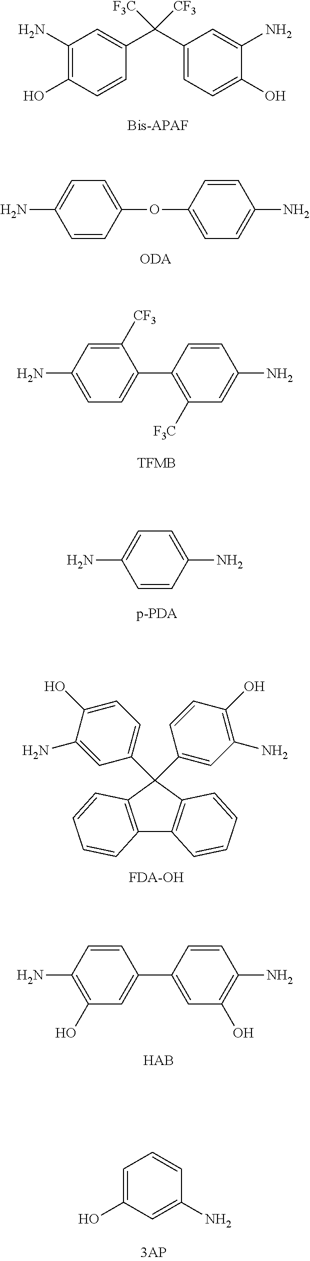

The anhydride-based monomer may be selected from the following structural formulae, but is not limited thereto.

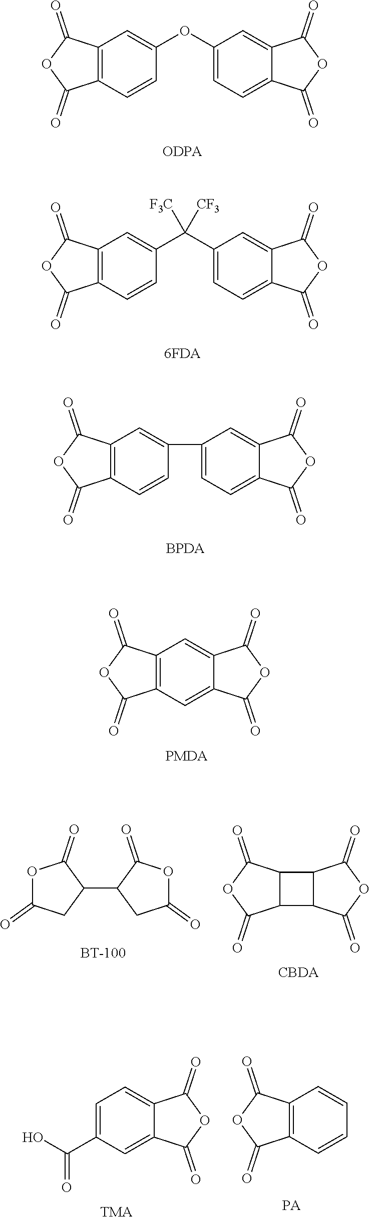

In an exemplary embodiment of the present application, the polyimide resin may further comprise units of the following structural formulae. The following structural formulae may be introduced into the polyimide resin from the amine-based monomers comprising the following structural formulae, the anhydride-based monomers comprising the following structural formulae, and the like.

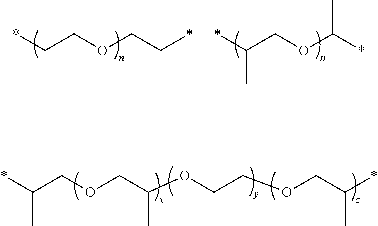

In the structural formulae,
* denotes a position to be bonded to the polyimide resin,
n is each independently a real number from 1 to 30, and
x, y and z are each independently a real number from 1 to 50.

In an exemplary embodiment of the present application, the functional group represented by Chemical Formula 1 or 2 may be bonded to both ends of the polyimide resin. Further, the functional group represented by Chemical Formula 1 or 2 may be bonded to any one end of the polyimide resin, and an end group known in the art may be bonded to the other end of the polyimide resin. For example, the functional group represented by Chemical Formula 1 or 2 may be bonded to any one end of the polyimide resin, and an end group of the following structural formulae may be bonded to the other end of the polyimide resin, but the end group is not limited thereto.

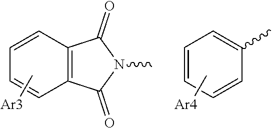

In the structural formulae,
[symbol] denotes a position to be bonded to the polyimide resin, respectively, and

Ar3 and Ar4 are the same as or different from each other, and are each independently hydrogen, a hydroxyl group, or a substituted or unsubstituted alkyl group.

In an exemplary embodiment of the present application, the polyimide resin may have a weight average molecular weight of 1,000 g/mol to 70,000 g/mol, more preferably 3,000 g/mol to 50,000 g/mol. When the weight average molecular weight of the polyimide resin is less than 1,000 g/mol, the produced polymer film may be brittle and the adhesive strength may deteriorate. In addition, when the weight average molecular weight of the polyimide resin exceeds 70,000 g/mol, the sensitivity is lowered and the polyimide resin may not be developed or scum may remain, which is not preferred.

The weight average molecular weight is one of the average molecular weights in which the molecular weight is not uniform and the molecular weight of any polymer material is used as a reference, and is a value obtained by averaging the molecular weight of a component molecular species of a polymer compound having a molecular weight distribution by a weight fraction.

The weight average molecular weight may be measured by a gel permeation chromatography (GPC) method.

The polyimide resin according to an exemplary embodiment of the present application is characterized in that the adhesion strength to a metal can be improved by directly comprising a functional group represented by Chemical Formula 1 or 2 as a functional group having excellent adhesion to the metal in the polyimide resin.

Further, another exemplary embodiment of the present application provides a method for preparing a polyimide resin, the method comprising: preparing a polyimide resin in which a functional group represented by the following Chemical Formula 10 or 11 is bonded to at least one end of the polyimide resin; and reacting the polyimide resin to which the functional group represented by Chemical Formula 10 or 11 is bonded with a heterocyclic compound comprising a thiol group (—SH).

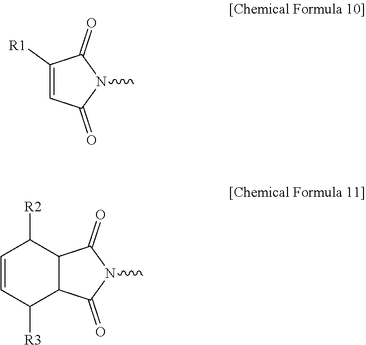

In Chemical Formulae 10 and 11,
[symbol] denotes a position to be bonded to the polyimide resin, respectively, and

R1 to R3 are each independently hydrogen, a substituted or unsubstituted alkyl group, a substituted or unsubstituted aryl group, or a substituted or unsubstituted heteroaryl group, and R2 and R3 may be linked to each other to form a ring.

In an exemplary embodiment of the present application, a method for reacting the polyimide resin to which the functional group represented by Chemical Formula 10 or 11 is bonded with the heterocyclic compound comprising a thiol group (—SH) was specifically described in Examples to be described below.

In an exemplary embodiment of the present application, the heterocyclic compound comprising a thiol group (—SH) may be selected from the following compounds.

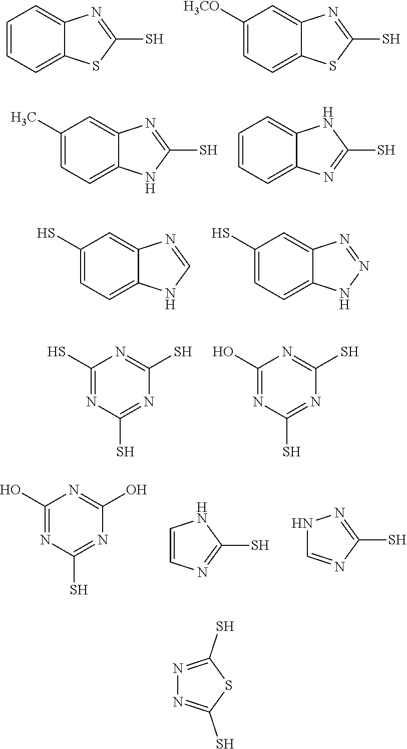

In addition, another exemplary embodiment of the present application provides a positive-type photosensitive resin composition comprising: a binder resin comprising the polyimide resin; a photoactive compound; a cross-linking agent; a surfactant; and a solvent.

In an exemplary embodiment of the present application, based on 100 parts by weight of the binder resin comprising the polyimide resin, it is possible to comprise 1 part by weight to 40 parts by weight of the photo active compound; 5 parts by weight to 50 parts by weight of the cross-linking agent; 0.05 part by weight to 5 parts by weight of the surfactant; and 50 parts by weight to 500 parts by weight of the solvent.

When each of the constituent elements is comprised in the positive-type photosensitive resin composition in the above-described range of parts by weight, the polyimide resin is developed in an alkaline developer and may not only have high mechanical properties and heat resistance, but also improve the adhesion strength to a metal.

The photo active compound may be specifically a quinonediazide compound. As the quinonediazide compound, for example, TPA529, THA515 or PAC430 manufactured by Miwon Commercial Co., Ltd. may be used, but the compound is not limited thereto.

The cross-linking agent is not particularly limited, and may be used without limitation as long as the cross-linking agent is applied to the art. For example, as the cross-linking agent, it is possible to use 2-[[4-[2-[4-[1,1-bis[4-(oxiran-2-ylmethoxy)phenyl]ethyl]phenyl]propan-2-yl]phenoxy]methyl]oxirane, 4,4′-methylenebis(N,N-bis(oxiran-2-ylmethyl)aniline), YD-127, YD-128, YD-129, YDF-170, YDF-175, and YDF-180 manufactured by Kukdo Chemical Co., Ltd., EXA-4850 manufactured by DIC Corporation, and the like.

The surfactant is a silicone-based surfactant or a fluorine-based surfactant, and specifically, as the silicone-based surfactant, it is possible to use BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341v344, BYK-345v346, BYK-348, BYK-354, BYK-355, BYK-356, BYK-358, BYK-361, BYK-370, BYK-371, BYK-375, BYK-380, BYK-390 and the like, which are manufactured by BYK-Chemie Co., Ltd., and as the fluorine-based surfactant, it is possible to use F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF1132, TF1027SF, TF-1441, TF-1442 and the like, which are manufactured by DaiNippon Ink & Chemicals, Inc. (DIC), but the surfactants are not limited thereto.

As the solvent, it is possible to employ a compound known to enable the formation of a photosensitive resin composition in the art to which the present invention pertains without particular limitation. As a non-limiting example, the solvent may be one or more compounds selected from the group consisting of esters, ethers, ketones, aromatic hydrocarbons, and sulfoxides.

The ester solvent may be ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, gamma-butyrolactone, epsilon-caprolactone, delta-valerolactone, alkyl oxyacetate (for example: methyl oxyacetate, ethyl oxyacetate, butyl oxyacetate (for example, methyl methoxyacetate, ethyl methoxyacetate, butyl methoxyacetate, methyl ethoxyacetate, ethyl ethoxyacetate, and the like)), 3-oxypropionic acid alkyl esters (for example: methyl 3-oxypropionate, ethyl 3-oxypropionate, and the like (for example, methyl 3-methoxypropionate, ethyl 3-methoxypropionate, methyl 3-ethoxypropionate, ethyl 3-ethoxypropionate, and the like)), 2-oxypropionic acid alkyl esters (for example: methyl 2-oxypropionate, ethyl 2-oxypropionate, propyl 2-oxypropionate, and the like (for example, methyl 2-methoxypropionate, ethyl 2-methoxypropionate, propyl 2-methoxypropionate, methyl 2-ethoxypropionate, ethyl 2-ethoxypropionate)), methyl 2-oxy-2-methylpropionate and ethyl 2-oxy-2-methylpropionate (for example, methyl 2-methoxy-2-methylpropionate, ethyl 2-ethoxy-2-methylpropionate, and the like), methyl pyruvate, ethyl pyruvate, propyl pyruvate, methyl acetoacetate, ethyl acetoacetate, methyl 2-oxobutyrate, ethyl 2-oxobutyrate, or the like.

The ether solvent may be diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, or the like.

The ketone solvent may be methyl ethyl ketone, cyclohexanone, cyclopentanone, 2-heptanone, 3-heptanone, N-methyl-2-pyrrolidone, or the like.

The aromatic hydrocarbon solvent may be toluene, xylene, anisole, limonene, or the like.

The sulfoxide solvent may be dimethyl sulfoxide or the like.

Another exemplary embodiment of the present application provides an insulating film comprising the positive-type photosensitive resin composition or a cured product thereof.

The insulating film may comprise the positive-type photosensitive resin composition as it is.

The insulating film may comprise a cured product of the positive-type photosensitive resin composition.

Examples of a light source for curing the photosensitive resin composition according to an exemplary embodiment of the present application comprise mercury vapor arc, carbon arc, Xe arc, and the like, which emit a light with a wavelength of 250 nm to 450 nm, but are not always limited thereto.

The insulating film may be further subjected to a step of heat-treating the positive-type photosensitive resin composition after curing the positive-type photosensitive resin composition, if necessary. The heat treatment may be performed by a heating means such as a hot plate, a hot air circulation furnace, and an infrared furnace, and may be performed at a temperature of 180° C. to 250° C., or 190° C. to 220° C.

The insulating film exhibits excellent chemical resistance and mechanical properties, and thus may be preferably applied to an insulating film of a semiconductor device, an interlayer insulating film for a redistribution layer, and the like. Further, the insulation may be applied to photoresists, etching resists, solder top resists, and the like.

The insulating film may comprise a support or substrate.

The support or substrate is not particularly limited, and those known in the art may be used. For example, a substrate for an electronic component or a predetermined wiring pattern formed on the substrate may be exemplified. Examples of the substrate comprise a metal substrate such as silicon, silicon nitride, titanium, tantalum, palladium, titanium tungsten, copper, chromium, iron, aluminum, gold, and nickel, a glass substrate, and the like. As a material of the wiring pattern, for example, copper, solder, chromium, aluminum, nickel, gold and the like may be used, but the material is not limited thereto.

The application method is not particularly limited, but a spray method, a roll coating method, a spin coating method, and the like may be used, and in general, the spin coating method is widely used. Further, an application film is formed, and then in some cases, the residual solvent may be partially removed under reduced pressure.

In an exemplary embodiment of the present application, the insulating film may have a thickness of 1 μm to 100 μm. When the thickness range of the insulating film is satisfied, it is possible to obtain an insulating film which is excellent not only in chemical resistance and mechanical properties, which are desired in the present application, but also in adhesion strength to a metal. The thickness of the insulating film may be measured using a scanning electron microscope (SEM).

Another exemplary embodiment of the present application provides a semiconductor device comprising the insulating film.

The semiconductor device may be manufactured by further comprising various parts typically used in the art in addition to the insulating film.

### MODE FOR INVENTION

Hereinafter, the present application will be described in detail with reference to Examples for specifically describing the present application. However, the Examples according to the present application may be modified in various forms, and it is not interpreted that the scope of the present application is limited to the Examples described below. The Examples of the present application are provided for more completely explaining the present application to the person with ordinary skill in the art.

### EXAMPLES

### Synthesis Example 1

### Synthesis of Polyimide Resin A1

100 mmol of Bis-APAF and 300 g of propylene glycol methyl ether acetate (PGMEA) were sequentially added to a 1,000-mL round bottom flask, the temperature was increased to 120° C., and the resulting mixture was stirred and completely dissolved. The flask was cooled to 80° C., 97 mmol of PMDA and 6 mmol of MA having the following structural formula were added thereto, and the resulting mixture was stirred with 30 g of toluene at 150° C. After the components were completely dissolved, the resulting solution was cooled to 50° C., and then 3 mmol of gamma valerolactone (r-VL) and 7 mmol of triethyl amine were diluted with 10 g of propylene glycol monomethyl acetate, and the resulting solution was introduced thereinto. After a Dean-Stark distillation apparatus was installed such that water could be removed in the reaction by the apparatus, the mixture was stirred at 175° C. for 16 hours. After the toluene added to the mixed solution was removed, the solution was cooled to room temperature and recovered. The weight average molecular weight (Mw) of the recovered polymer was confirmed using gel permeation chromatography (GPC), and was determined to be 16,112 g/mol. In addition, the polydispersity index (PDI) of the prepared polymer was 2.18.

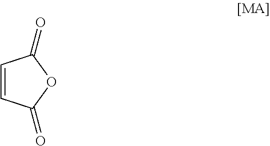

### Synthesis Example 2

### Synthesis of Polyimide Resin B1

Polyimide resin B1 was synthesized in the same manner as in the synthesis of polyimide resin A1, except that TFMB and BPDA were used instead of Bis-APAF and PMDA, respectively. The weight average molecular weight (Mw) and polydispersity index (PDI) of the recovered polymer were 15,998 g/mol and 2.16, respectively.

### Synthesis Example 3

### Synthesis of Polyimide Resin C1

Polyimide resin C1 was synthesized in the same manner as in the synthesis of polyimide resin A1, except that 50 mmol of Bis-APAF and 50 mmol of ODA were used instead of 100 mmol of Bis-APAF, and 47 mmol of PMDA and 50 mmol of ODPA were used instead of 97 mmol of PMDA. The weight average molecular weight (Mw) and polydispersity index (PDI) of the recovered polymer were 18,055 g/mol and 2.29, respectively.

### Synthesis Example 4

### Synthesis of Polyimide Resin D1

Polyimide resin D1 was synthesized in the same manner as in the synthesis of polyimide resin Al, except that 50 mmol of TFMB and 50 mmol of HAB were used instead of 100 mmol of Bis-APAF, and 47 mmol of BPDA and 50 mmol of ODPA were used instead of 97 mmol of PMDA. The weight average molecular weight (Mw) and polydispersity index (PDI) of the recovered polymer were 14,911 g/mol and 2.62, respectively.

### Synthesis Example 5

### Synthesis of Polyimide Resin E1

Polyimide resin E1 was synthesized in the same manner as in the synthesis of polyimide resin A1, except that 50 mmol of Bis-APAF and 50 mmol of polyetheramine (ED-900, Jeffamine) were used instead of 100 mmol of Bis-APAF, and ODPA was used instead of PMDA. The weight average molecular weight (Mw) and polydispersity index (PDI) of the recovered polymer were 15,618 g/mol and 2.26, respectively.

### Synthesis Example 6

### Synthesis of Polyimide Resin A2

Polyimide resin A2 was synthesized in the same manner as in the synthesis of polyimide resin Al, except that iBF of the following structural formula was used instead of MA. The weight average molecular weight (Mw) and polydispersity index (PDI) of the recovered polymer were 18,485 g/mol and 2.46, respectively.

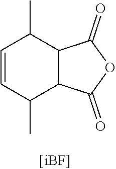

### Synthesis Example 7

### Synthesis of Polyimide Resin B2

Polyimide resin B2 was synthesized in the same manner as in the synthesis of polyimide resin B1, except that iBF was used instead of MA. The weight average molecular weight (Mw) and polydispersity index (PDI) of the recovered polymer were 17,489 g/mol and 2.41, respectively.

### Synthesis Example 8

### Synthesis of Polyimide Resin C2

Polyimide resin C2 was synthesized in the same manner as in the synthesis of polyimide resin C1, except that iBF was used instead of MA. The weight average molecular weight (Mw) and polydispersity index (PDI) of the recovered polymer were 17,918 g/mol and 2.45, respectively.

### Synthesis Example 9

### Synthesis of Polyimide Resin D2

Polyimide resin D2 was synthesized in the same manner as in the synthesis of polyimide resin D1, except that iBF was used instead of MA. The weight average molecular weight (Mw) and polydispersity index (PDI) of the recovered polymer were 18,007 g/mol and 2.46, respectively.

### Synthesis Example 10

### Synthesis of Polyimide Resin E2

Polyimide resin E2 was synthesized in the same manner as in the synthesis of polyimide resin El, except that iBF was used instead of MA. The weight average molecular weight (Mw) and polydispersity index (PDI) of the recovered polymer were 15,152 g/mol and 2.12, respectively.

### Synthesis Example 11

### Synthesis of Polyimide Resin A3

Polyimide resin A3 was synthesized in the same manner as in the synthesis of polyimide resin A1, except that 3AP was used instead of MA. The weight average molecular weight (Mw) and polydispersity index (PDI) of the recovered polymer were 17,475 g/mol and 2.35, respectively.

### Synthesis Example 12

### Synthesis of Polyimide Resin B3

Polyimide resin B3 was synthesized in the same manner as in the synthesis of polyimide resin B 1, except that PA was used instead of MA. The weight average molecular weight (Mw) and polydispersity index (PDI) of the recovered polymer were 16,341 g/mol and 2.23, respectively.

### Examples 1 to 20

### 1) Synthesis of Polyimide Resin and Thiol

2 equivalents of the thiol compound and 1 equivalent of the polyimide resin shown in the following Table 1, and 0.1 equivalent of the photoinitiator (benzophenone) were put into a flask and irradiated with 350 nm UV at room temperature for 4 hours. After the reaction, the polyimide was dissolved in THF and the precipitate was captured using hexane to remove unreacted materials and impurities.

### 2) Preparation of Positive-Type Photosensitive Resin Composition

A positive-type photosensitive resin composition was prepared by mixing 15 parts by weight of a photo active compound (TPA529), 25 parts by weight of a cross-linking agent (2-[[4-[2-[4-[1,1-bis [4-(oxiran-2-ylmethoxy)phenyl]ethyl]phenyl]propan-2-yl]phenoxy] methyl]oxirane), 0.1 part by weight of a surfactant (BYK-307, manufactured by BYK-Chemie) and 200 parts by weight of a solvent (PGMEA) based on 100 parts by weight of the polyimide resin prepared in 1).

### Comparative Examples 1 to 5

Positive-type photosensitive resin compositions were prepared in the same manner as in the Examples, except that the polyimide resins shown in the following Table 1 were applied.

### Comparative Examples 6 and 7

Positive-type photosensitive resin compositions were prepared in the same manner as in the Examples, except that the polyimide resins shown in the following Table 1 were applied and 2 equivalents of thiol compound T1 based on 1 equivalent of the polyimide resin were added.

### Experimental Example

The positive-type photosensitive resin compositions prepared in the Examples and Comparative Examples were allowed to pass through a 0.2-μm filter and evaluated by removing impurities in the solution.

After a wafer was spin-coated with the prepared positive-type photosensitive resin composition using a wafer on which Ti and Cu were vapor-deposited to a thickness of 100 nm or more, and coated to a thickness of 6 μm, the solvent remaining on the wafer was completely removed by baking at a temperature of 105° C. or more in order to remove the solvent. After the wafer was irradiated with a constant exposure of 100 mJ/cm² to 900 mJ/cm² using a stepper that emits i-line wavelength, the wafer was developed with a developer for 120 seconds, subjected to a rinsing process with a rinse solution, and then post baked at a temperature of 200° C. or less for 2 hours.

### [Evaluation Conditions of Positive-Type Photosensitive Resin Composition]

Prebake: 105° C./120 s

Exposure: i-line Stepper, 100 mJ/cm² to 900 mJ/cm²

Development: 2.38 wt % tetramethylammonium hydroxide (TMAH) solution 23° C./120 s

Rinse: DI water rinse

Post Bake: 200° C./2 hrs

The pattern characteristics were confirmed using a wafer that had been completely post baked, the photosensitive resin composition coated on the wafer was cured and then formed into a film, and the mechanical properties and thermal characteristics thereof were measured.

For pattern developability, the shape and size of the pattern were measured using a scanning electron microscope (SEM), and mechanical properties were measured using a universal testing machine (UTM).

### [Pattern Developability]

The shape and size of the pattern were measured by measuring a completely developed part from a thickness of 5 μm to a contact hole pattern lower part of 10 μm using the SEM, and a case where the hole pattern of 10 μm was completely developed was described as good. The case where the pattern lower part was not developed was described as poor.

Good: ⊚

Fair: Δ

Poor: X

### [Adhesion Strength]

A check shape of 10 rows, 10 columns was incised at an interval of 2 mm using a single-edged blade on a film after the wafer was coated with the resin and the resin was cured. The number of cells peeled out of 100 cells on top of this was counted by peeling with a cellophane tape (registered trademark) to evaluate the adhesion characteristics between the metal material and the resin-cured film.

Less than 10: ⊚

10 or more and less than 20: Δ

20 or more: X

TABLE 1

| | Binder resin | | | |
|---|---|---|---|---|
| | | Thiol | Pattern | Adhesion |
| | Polyimide resin | compound | developability | strength |
| Example 1 | A1 | T1 | ⊚ | ⊚ |
| Example 2 | B1 | T1 | ⊚ | ⊚ |
| Example 3 | C1 | T1 | ⊚ | ⊚ |
| Example 4 | D1 | T1 | ⊚ | ⊚ |
| Example 5 | E1 | T1 | ⊚ | ⊚ |
| Example 6 | A2 | T1 | ⊚ | ⊚ |
| Example 7 | B2 | T1 | ⊚ | ⊚ |
| Example 8 | C2 | T1 | ⊚ | ⊚ |
| Example 9 | D2 | T1 | ⊚ | ⊚ |
| Example 10 | E2 | T1 | ⊚ | ⊚ |
| Example 11 | A1 | T2 | ⊚ | ⊚ |
| Example 12 | B1 | T2 | ⊚ | ⊚ |
| Example 13 | C1 | T2 | ⊚ | ⊚ |
| Example 14 | D1 | T2 | ⊚ | ⊚ |
| Example 15 | E1 | T2 | ⊚ | ⊚ |
| Example 16 | A2 | T2 | Δ | ⊚ |
| Example 17 | B2 | T2 | ⊚ | ⊚ |
| Example 18 | C2 | T2 | Δ | ⊚ |
| Example 19 | D2 | T2 | ⊚ | ⊚ |
| Example 20 | E2 | T2 | ⊚ | ⊚ |
| Comparative | A1 | X | X | X |
| Example 1 | | | | |
| Comparative | B1 | X | Δ | X |
| Example 2 | | | | |
| Comparative | C1 | X | X | X |
| Example 3 | | | | |
| Comparative | D1 | X | Δ | X |
| Example 4 | | | | |
| Comparative | E1 | X | Δ | X |
| Example 5 | | | | |
| Comparative | A3 | X | Δ | Δ |
| Example 6 | | | | |
| Comparative | B3 | X | X | Δ |
| Example 7 | | | | |

### [Thiol Compound]

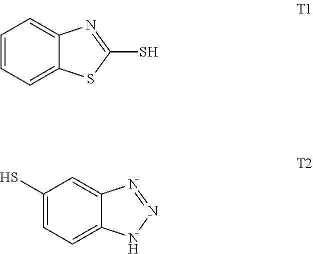 [SMILES: Sc1nc2ccccc2s1 ; Sc1ccc2[nH]nnc2c1]

As shown in the results, the polyimide resin according to an exemplary embodiment of the present application is characterized in that the adhesion strength to a metal can be improved by directly comprising a functional group having excellent adhesion to the metal in the polyimide resin.

Furthermore, Comparative Examples 6 and 7 are the cases where a thiol compound is separately comprised in a photosensitive resin composition instead of applying a polyimide resin in which a thiol-based functional group is directly bonded to the polyimide resin as in the examples of the present application. As shown in the results, it can be confirmed that in the case of Comparative Examples 6 and 7, pattern developability and adhesion strength characteristics are not good when compared to the examples of the present application.

Therefore, a photosensitive resin composition comprising the polyimide resin according to an exemplary embodiment of the present application can improve the adhesion strength to a metal even when the photosensitive resin composition does not comprise a separate adhesion promoter.

1. A polyimide resin in which a functional group represented by the following Chemical Formula 1 or 2 is bonded to at least one end of the polyimide resin: 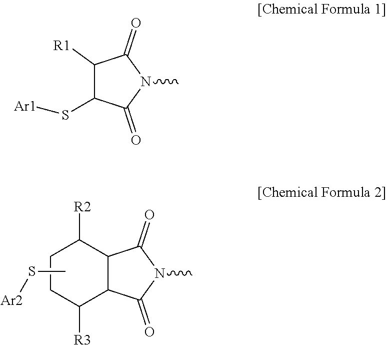
in Chemical Formulae 1 and 2, [symbol]
denotes a position to be bonded to the polyimide resin, respectively,
R1 to R3 are each independently hydrogen, a substituted or unsubstituted alkyl group, a substituted or unsubstituted aryl group, or a substituted or unsubstituted heteroaryl group, and R2 and R3 are optionally linked to each other to form a ring, and
Ar1 and Ar2 are each independently a substituted or unsubstituted heteroaryl group.

2. The polyimide resin of claim 1, where Chemical Formula 1 is represented by the following Chemical Formula 3 or 4: 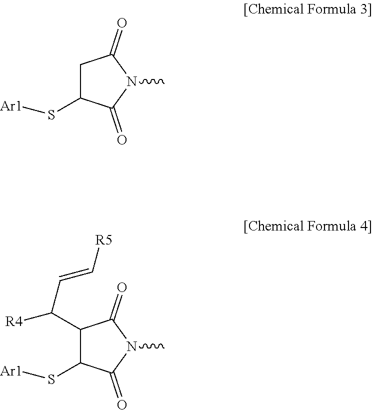
in Chemical Formulae 3 and 4, [symbol]
denotes a position to be bonded to the polyimide resin, respectively,
R4 and R5 are each independently hydrogen, or a substituted or unsubstituted alkyl group, and
Ar1 is a substituted or unsubstituted heteroaryl group.

3. The polyimide resin of claim 1, wherein Chemical Formula 2 is any one of the following Chemical Formulae 5 to 9: 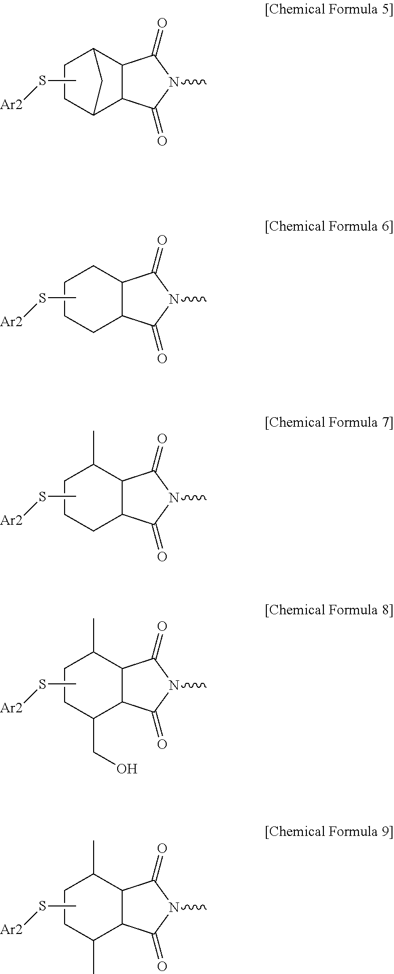
in Chemical Formulae 5 to 9, [symbol]
denotes a position to be bonded to the polyimide resin, respectively, and
Ar2 is a substituted or unsubstituted heteroaryl group.

4. The polyimide resin of claim 1, wherein Ar1 and Ar2 of Chemical Formulae 1 and 2 are each independently represented by any one of the following structural formulae: 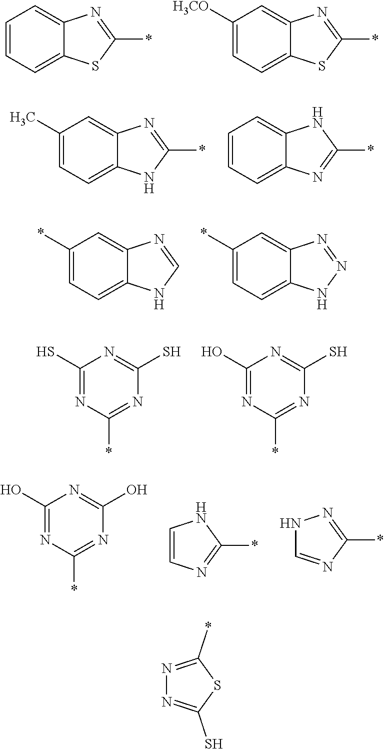
in the structural formulae, * denotes a position to be bonded to Chemical Formula 1 or 2.

5. The polyimide resin of claim 1, wherein the polyimide resin comprises a polymer product of an amine-based monomer and an anhydride-based monomer.

6. The polyimide resin of claim 5, wherein the amine-based monomer is selected from the following structural formulae:

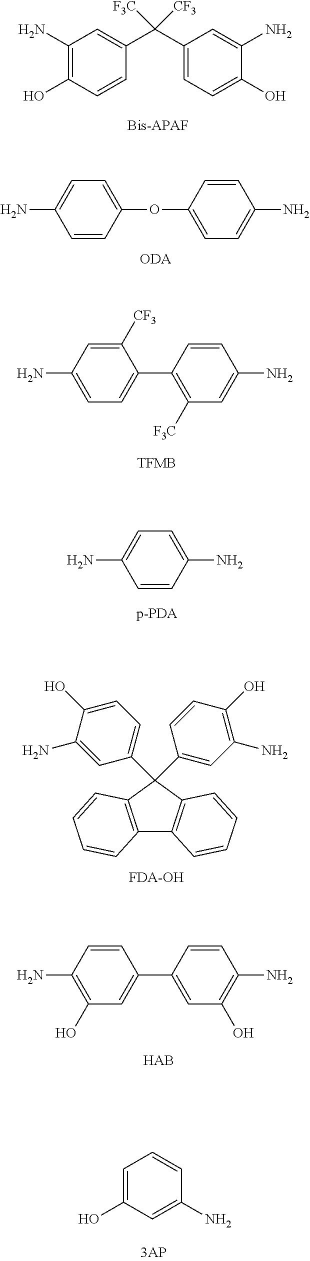

7. The polyimide resin of claim 5, wherein the anhydride-based monomer is selected from the following structural formulae:

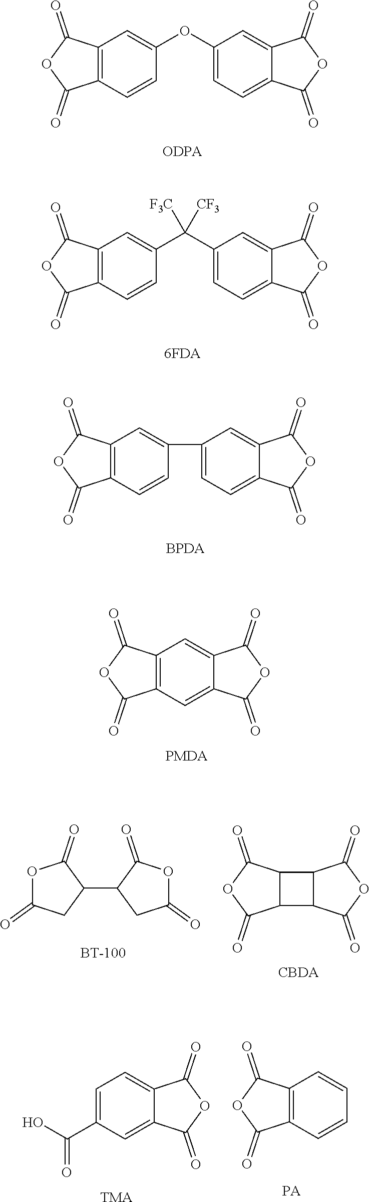

8. A method for preparing a polyimide resin, the method comprising:
preparing a polyimide resin in which a functional group represented by the following Chemical Formula 10 or 11 is bonded to at least one end of the polyimide resin; and
reacting the polyimide resin to which the functional group represented by Chemical Formula 10 or 11 is bonded with a heterocyclic compound comprising a thiol group (—SH): 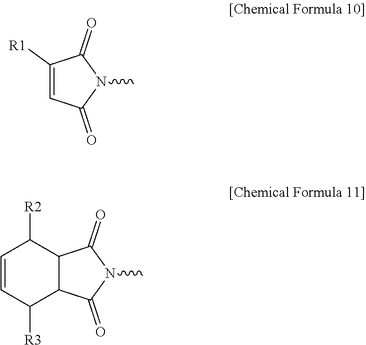
in Chemical Formulae 10 and 11, [symbol]
denotes a position to be bonded to the polyimide resin, respectively, and
R1 to R3 are each independently hydrogen, a substituted or unsubstituted alkyl group, a substituted or unsubstituted aryl group, or a substituted or unsubstituted heteroaryl group, and R2 and R3 are optionally linked to each other to form a ring.

9. The method of claim 8, wherein the heterocyclic compound comprising a thiol group (—SH) is selected from the following compounds:

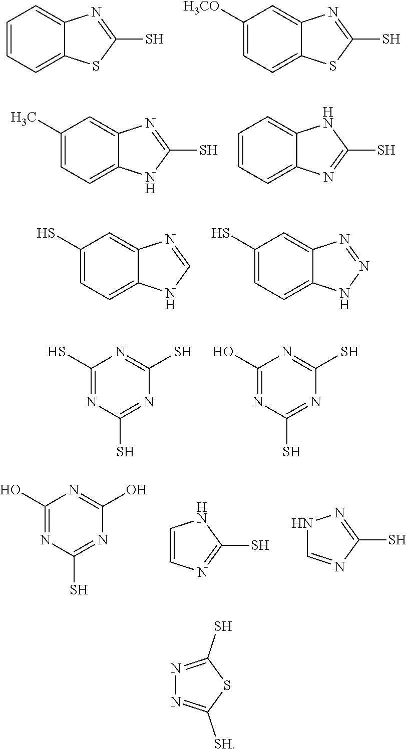

10. A positive-type photosensitive resin composition comprising:
a binder resin comprising the polyimide resin of claim 1;
a photo active compound;
a cross-linking agent;
a surfactant; and
a solvent.

11. The positive-type photosensitive resin composition of claim 10, wherein based on 100 parts by weight of the binder resin comprising the polyimide resin,
1 part by weight to 40 parts by weight of the photo active compound;
5 parts by weight to 50 parts by weight of the cross-linking agent;
0.05 part by weight to 5 parts by weight of the surfactant; and
50 parts by weight to 500 parts by weight of the solvent are comprised.
